(19) United States
(12) Patent Application Publication
(10) Pub. No.: US 2020/0376816 A1
(43) Pub. Date: Dec. 3, 2020

(54) HEATABLE VACUUM RING

(71) Applicant: SAINT-GOBAIN GLASS FRANCE, COURBEVOIE (FR)

(72) Inventors: Stefan LÜCKE, Spenge (DE); Raphaela KANNENGIESSER, Aachen (DE); Stephan GIER, Bous (DE); Bernhard REUL, Herzogenrath (DE)

(21) Appl. No.: 16/770,270

(22) PCT Filed: Dec. 3, 2018
(86) PCT No.: PCT/EP2018/083275

§ 371 Date: Jun. 5, 2020

(30) Foreign Application Priority Data
Dec. 7, 2017 (EP) 17205823.2

(51) Int. Cl. B32B 17/10; H05B 3/12; H05B 3/58; H05B 3/18; C03C 27/10; B32B 37/10; B32B 37/18; B32B 37/12

(52) U.S. Cl. CPC B32B 17/10972; B32B 2457/12; H05B 3/58; H05B 3/18; B32B 17/10036; B32B 17/10761; C03C 27/10; B32B 17/10844; B32B 37/1018; B32B 37/182; B32B 37/12; H05B 2203/003; H05B 2203/007; H05B 2203/016; B32B 2605/00; B32B 2037/1223; H05B 3/12

(57) ABSTRACT

A vacuum ring for deaerating a stack sequence includes a vacuum-stable flexible hose, which can be connected to a vacuum pump, has the shape of a closed ring, and has an opening to the interior such that the ring can hold an outer side edge of a stack sequence in order to form a deaeration channel along the side edge, wherein the vacuum ring has at least one electric heating element.

The invention relates to a heatable vacuum ring, its use in a method for deaerating a stack sequence, and a method for deaerating a stack sequence.

Stack sequences can be used in particular for producing a composite pane or a solar generator.

Composite panes are widely used, for example, as vehicle panes, such as windshields, side windows, rear windows, or roof panels in vehicles on water, on land, or in the air, but also as architectural panes, as fire protection panes, as safety glazing, or in furniture as well as movable or permanently mounted furnishings.

Composite panes typically comprise at least two panes, for example, a substrate pane and a cover pane joined together via at least one thermoplastic intermediate layer, for example, made of a thermoplastic polyvinyl butyral (PVB) film, in a lamination process under the action of heat and pressure.

Solar generators typically comprise solar cells, thermoplastic films arranged on the top and bottom sides thereof, and two outer glass panes joined together under the action of heat and pressure.

Both with composite panes and with solar generators, it is generally desirable to avoid bubbles between the respective layers of the stack sequence during the respective manufacturing process and/or to remove existing bubbles between the respective layers in order to improve the quality of the product.

Industrially common methods for producing composite panes usually include a deaeration process combined with an autoclave process, as disclosed in U.S. Pat. Nos. 2,948,645 and 4,781,783. For production of solar generators as well, a deaeration process is usually combined with an autoclave process, as disclosed in DE 3544080 A1. The prior art methods are very energy intensive since, therein, the entire stack sequence is heated to seal an edge region of the deaerated stack sequence.

The object of the present invention consists in providing an improved vacuum ring that enables deaerating a stack sequence and heating it locally in the region of the side edge of the stack sequence and/or in a region adjacent the side edge, and, thus, sealing it under a vacuum.

The object of the present invention is accomplished according to the invention by a vacuum ring in accordance with the independent claim 1. Preferred embodiments are apparent from the dependent claims.

The term “stack sequence” refers here and in the following in particular to a stacked arrangement of panes and thermoplastic films or a stacked arrangement of panes, solar cells, and thermoplastic films, for example, a stack sequence for producing a composite pane or a solar generator. Particularly preferably, a “stack sequence” means a stack sequence for producing a composite pane, i.e., a stack sequence comprising at least two panes and at least one intermediate thermoplastic film.

The invention relates to a vacuum ring for deaerating a stack sequence. The vacuum ring according to the invention comprises a vacuum-stable flexible hose that can be connected to a vacuum pump. The hose has the shape of a closed ring. According to the invention, the hose is open to the interior, i.e., it has an opening to the interior of the ring formed by the hose. The hose can be arranged around an outer side edge of a stack sequence such that the outer side edge of the stack sequence is held in the opening of the ring. The hose of the vacuum ring can thus be placed circumferentially around the stack sequence on the outer side edge of a stack sequence. The opening of the hose is implemented such that the outer side edge of the stack sequence can be held such that a deaeration channel is formed. For example, the opening of the hose can have a substantially pentagonal shape. However, a C-shaped or U-shaped opening is, for example, also possible.

The vacuum ring according to the invention completely encloses the side edges of the stack sequence and the intermediate space between the individual panes and/or films of the stack sequence and seals it using vacuum technology. As a result of applying a vacuum to the vacuum ring, the air can be removed from the deaeration channel and from the intermediate space between the individual panes and/or films.

According to the invention, the vacuum ring has at least one electric heating element and is thus a heatable vacuum ring. The vacuum ring can, for example, have one, two, three, four, five, six, or more heating elements.

As used here and below, the term “heating element” refers to an electrical component that converts electrical energy into thermal energy, i.e., heat.

Preferably, the electric heating element has a connection element for connecting to a voltage source. The connection of the connection element to the voltage source can be made with or without contact. In the case of a contactless connection, the voltage of the voltage source is induced in the connection element.

The connection element can have any shape suitable for connecting to a voltage source. It can, for example, be a plug connection or a plate in which voltage can be induced.

As a result of the application of a voltage on the electric heating element, the heating element and also, consequently, the region of the hose adjacent the heating element are heated. The region of the stack sequence that is arranged adjacent the heated regions of the hose and/or of the heating element is likewise heated thereby. Consequently, the at least one thermoplastic film of the stack sequence is also heated in this region and melts or softens at a sufficient temperature of, for example, 70° C. to 100° C. In this way, the panes of the stack sequence can be joined together in this region and sealed airtightly. If the electric heating element has a connection element for connecting to a voltage source, the voltage is applied to the electric heating element by connecting the connection element to a voltage source.

In one embodiment, the electric heating element is at least partially embedded in the hose, more precisely, in the mass of the hose, and/or glued to the hose.

Preferably, the electric heating element is at least partially embedded in the hose.

In an advantageous embodiment, the electric heating element is completely enclosed by the material of the hose.

In a preferred embodiment, the electric heating element extends over the entire length of the hose. This embodiment enables complete sealing of the stack sequence in the region adjacent the side edge. It can thus be insured that air cannot again penetrate between the individual layers of the stack sequence after it has been evacuated and sealed.

In another embodiment, individual electric heating elements are arranged in or on the hose in individual sections of the hose in each case. In this manner, selective heating of individual sections of the hose and, thus, section-wise sealing of the stack sequence can be achieved.

The electric heating element can have any suitable form. Preferably, the electric heating element is implemented in the form of a wire or strip.

A heating element implemented as a wire preferably has a diameter between 0.05 mm and 5 mm, particularly preferably between 0.1 mm and 3 mm, most particularly preferably between 0.3 mm and 2 mm, for example, 1 mm.

A heating element implemented as a strip preferably has a width between 5 mm and 12 mm, particularly preferably between 6 mm and 10 mm, most particularly preferably between 7 mm and 9 mm, for example, 8 mm or 5 mm. The thickness of a heating element implemented as a strip preferably is between 0.01 mm and 2 mm, particularly preferably between 0.01 mm and 0.5 mm, most particularly preferably between 0.03 mm and 0.1 mm, for example, 0.05 mm or 0.1 mm.

The dimensions of the hose, i.e., the size of the opening and the length of the hose, are adapted to the thickness and the circumference of the stack sequence to be deaerated. The wall thickness of the hose is adapted to the thickness and the number of heating elements and is preferably 3 mm to 10 mm, particularly preferably 5 mm to 7 mm.

In advantageous embodiments, the electric heating element is implemented as a-wave-shaped, meander-shaped, or spiral-shaped wire or a wave-shaped, meander-shaped, or spiral-shaped strip.

A wave-shaped, meander-shaped, or spiral-shaped embodiment has an advantageous effect on the flexibility and the durability of the heating element. In the case of expansion of the material of the hose, heating elements thus implemented can be deformed accordingly without kinks or breaks occurring.

In one embodiment, the electric heating element is arranged directly adjacent the opening of the hose. In this case, the heating element can come into direct contact with the stack sequence to be deaerated during evacuation of the vacuum ring. Preferably, the heating element does not come into contact with the outer side edge of the stack sequence to be deaerated.

In an advantageous embodiment, the electric heating element is arranged such that when the outer side edge of the stack sequence is held in the vacuum ring, the heating element is arranged outside, in particular completely outside, the deaeration channel formed in the evacuated state. This ensures that the electric heating element does not make contact with the side edge of the stack sequence.

Making contact with the side edge of the stack sequence that has a thermoplastic intermediate layer could result in the fact that upon heating of the heating element and evacuation of the vacuum ring, the thermoplastic intermediate layer is partially sucked into the deaeration channel and/or the heating element is bonded to the thermoplastic intermediate layer emerging from the stack sequence. In addition, making contact with the side edge could result in a poor seal between the vacuum ring and the stack sequence, resulting in poor deaeration of the stack sequence upon heating of the heating element and evacuation of the vacuum ring.

In one embodiment, the electric heating element is made of a metal or a metal alloy. Preferably, the electric heating element is made of copper, a copper alloy, a nickel alloy, a nickel-copper alloy, or a nickel-chromium alloy. Particularly preferably, the electric heating element is made of copper or a copper alloy. The electrical heating element can, for example, be a copper wire, a copper strip, or a wire or strip made of a copper alloy.

The electric heating element can, optionally, be at least partially coated with at least one insulating layer. Nonconductive lacquers and/or plastics are in particular suitable as an insulating layer. The insulating layer can, for example, prevent or at least minimize damage to the heating element, such as corrosion and the like. Furthermore, an insulating layer can serve to prevent a user of the vacuum ring from being able to come into direct contact with the current-carrying parts of the vacuum ring.

In one embodiment, the electric heating element is completely enclosed by an insulating layer. In an alternative embodiment, the heating element is only partially coated with an insulating layer.

As a result of application of a suitable voltage, i.e., by connection of the heating element to a voltage source, the electric heating element can heat up. In one embodiment, the electric heating element heats up, upon application of a voltage, to 20° C. to 160° C., preferably to 50° C. to 150° C., particularly preferably to 70° C. to 130° C., most particularly preferably to 90° C. to 110° C., for example, to 100° C.

As described above, the connection of the heating element to a voltage source can be accomplished, for example, in that the heating element has a connection element and this is connected with or without contact to the voltage source.

In an advantageous embodiment, the vacuum ring has at least two electric heating elements, wherein at least one electric heating element is arranged in or on the hose above the opening of the hose and at least one electric heating element is arranged in or on the hose below the opening of the hose. For example, the vacuum ring can have exactly two electric heating elements, of which one is arranged above and one below the opening. The vacuum ring can, however, also have four electric heating elements, of which two are arranged above and two below the opening. In another embodiment, the vacuum ring has six electric heating elements, of which three are arranged above and three below the opening.

In an advantageous embodiment, the vacuum-stable flexible hose of the vacuum ring according to the invention is made of an elastomer. For example, the hose can be made of silicone, rubber, or synthetic rubber, in particular ethylene-propylene-diene rubber (EPDM).

The vacuum ring according to the invention can be connected to the vacuum pump via a vacuum hose. Optionally, a vacuum compensation tank can be arranged between the vacuum hose and the vacuum pump. The vacuum ring and the vacuum hose can, for example, be connected to one another via a tee inserted into the vacuum ring. Preferably, the combination of the vacuum ring and the vacuum hose is implemented in one piece.

The at least one heating element can be electrically connected to a voltage source, in particular via a connection element as previously described. In the case of more than one heating element, the heating elements can either all be connected to the same voltage source or to different voltage sources, wherein multiple heating elements are preferably connected to the same voltage source.

Together, the vacuum ring, vacuum hose, optional vacuum compensation tank, vacuum pump, and the at least one electrically connected voltage source form a vacuum system according to the invention.

In one embodiment of the vacuum system, the vacuum hose with the vacuum pump connected via an optional vacuum compensation tank and the at least one voltage source are arranged on the same side of the vacuum ring, preferably adjacent one another. In another embodiment of the vacuum systems, the vacuum hose with the vacuum pump connected via an optional vacuum compensation tank and the at least one voltage source are arranged on opposite sides of the vacuum ring. In principle, the arrangement of the vacuum hose with the vacuum pump connected via an optional vacuum compensation tank and the arrangement of the at least one voltage source can be done independently of one another at any position on the vacuum ring.

In the embodiment in which the electric heating element has a connection element for connecting to a voltage source, the vacuum hose with the vacuum pump connected via an optional vacuum compensation tank and the connection element for connecting to a voltage source are arranged on the same side of the vacuum ring, preferably adjacent one another. In another embodiment of the vacuum system, the vacuum hose with the vacuum pump connected via an optional vacuum compensation tank and the connection element for connecting to a voltage source are arranged on opposite sides of the vacuum ring. In principle, the arrangement of the vacuum hose connected to the vacuum pump connected via an optional vacuum compensation tank and the arrangement of the connection element for connecting to a voltage source can be done independently of one another at any point on the vacuum ring.

The vacuum compensation tank has, for example, a volume of 1 m³. The vacuum pump has, for example, a pumping capacity of 300 m³/h and reaches a maximum final pressure of 0.1 mbar.

The invention also relates to a method for deaerating a stack sequence, at least comprising arranging a stack sequence, arranging a vacuum ring according to the invention around the outer side edge of the stack sequence, applying a vacuum, i.e., a negative pressure, to the vacuum ring, and applying a voltage to the at least one electric heating element, which the vacuum ring according to the invention has. As a result of applying a negative pressure of, for example, at least −0.9 bar to the vacuum ring, the air between the layers of the stack sequence is removed. The electrical energy of the voltage source is converted into thermal energy by the electric heating element and the heating element heats up. As explained in detail above, this also locally heats up the stack sequence and the at least one thermoplastic film contained therein such that the stack sequence is bonded together in this region. The application of a vacuum and the application of a voltage on the at least one heating element can even be carried out simultaneously.

The embodiment, in which the application of a vacuum and the application of a voltage on the at least one heating element occur simultaneously, is a particularly preferred embodiment of the method according to the invention.

In one embodiment, a voltage is applied to the electric heating element that is suitable for heating the electric heating element to 20° C. to 160° C., preferably to 50° C. to 150° C., particularly preferably to 70° C. to 130° C., most particularly preferably to 90° C. to 110° C., for example, to 100° C.

The invention also includes the use of a vacuum ring according to the invention in a method for deaerating a stack sequence, wherein the stack sequence is in particular a stack sequence for producing a composite pane or a solar generator.

The panes of the stack sequence preferably contain glass, particularly preferably flat glass, even more preferably float glass, and in particular quartz glass, borosilicate glass, soda lime glass, or clear plastics, preferably rigid clear plastics, in particular polyethylene, polypropylene, polycarbonate, polymethyl methacrylate, polystyrene, polyamide, polyesters, polyvinyl chloride, and/or mixtures thereof. The panes are preferably transparent, in particular for the use of the composite pane produced from the stack sequence as a windshield or rear window of a vehicle or other uses in which high light transmittance is desirable. In the context of the invention, “transparent” refers to a pane having transmittance greater than 70% in the visible spectral range. For panes that are not within the traffic-relevant field of vision of the driver, for example, for roof panels, the transmittance can however also be much lower, for example, greater than 5%.

The thickness of the panes can vary widely and thus be adapted to the requirements of the individual case. Preferably used are standard thicknesses from 0.5 mm to 25 mm, preferably from 1.4 mm to 2.5 mm for vehicle glass, and preferably from 4 mm to 25 mm for furniture, appliances, and buildings, in particular for electric radiators. The size of the panes can vary widely and is governed by the size of the application. The panes have, for example, in vehicle construction and architecture, customary areas from 200 cm² up to 20 m².

The panes of the stack sequence are joined to one another by at least one intermediate layer. The intermediate layer is preferably transparent. The intermediate layer preferably contains at least one plastic, preferably polyvinyl butyral (PVB), ethylene vinyl acetate (EVA), and/or polyethylene terephthalate (PET). The intermediate layer can, however, also contain, for example, polyurethane (PU), polypropylene (PP), polyacrylate, polyethylene (PE), polycarbonate (PC), polymethyl methacrylate, polyvinyl chloride, polyacetate resin, casting resins, acrylates, fluorinated ethylene propylene, polyvinyl fluoride, and/or ethylene tetrafluoroethylene, or copolymers or mixtures thereof.

The intermediate layer can be formed by one or also by a plurality of films arranged above one another, wherein the thickness of a film is preferably from 0.025 mm to 2 mm, typically 0.38 mm or 0.76 mm or 1.52 mm. In other words, the intermediate layer can in each case be constructed from one or a plurality of films. Preferred in this case are at least three films arranged above one another, in particular polyvinyl butyral films, with alternating different plasticity or elasticity, as are known, for example, from EP 0763420 A1 or EP 0844075 A1.

The intermediate layers can preferably be thermoplastic, and, after heating, bond the panes and any further intermediate layers to one another.

The total thickness of the stack sequence to be deaerated is preferably between 2 mm and 30 mm.

Vacuum rings according to the invention adapted to the size of the panes of the stack sequence with openings adapted to the total thickness of the stack sequence to be deaerated ensure that the vacuum ring according to the invention completely encloses the side edges of the stack sequence and the intermediate space between the individual panes and/or films of the stack sequence and seals it using vacuum technology.

Vacuum rings according to the invention can, for example, be produced by placing the at least one electric heating element and then extruding the mass of the hose around it. This production method is suitable in particular for vacuum rings according to the invention, in which the at least one electric heating element is at least partially embedded in the mass of the hose.

Vacuum rings according to the invention, in which the at least one electric heating element is glued onto the mass of the hose, can, for example, be produced by first producing the hose using an extrusion method, and then gluing the at least one electric heating element onto the hose with a temperature-resistant adhesive.

The various embodiments of the invention can be realized individually or in any combinations. In particular, the features mentioned above and explained below can be used not only in the combinations indicated, but also in other combinations or in isolation without departing from the scope of the present invention.

It goes without saying that the embodiments described for an electric heating element can, in those cases in which the vacuum ring has more than one electric heating element, be transferred to the respective number of electrical heating elements.

The invention is now explained in detail using exemplary embodiments and referring to the accompanying figures. The figures in no way restrict the invention. In a simplified, not to scale representation, they depict:

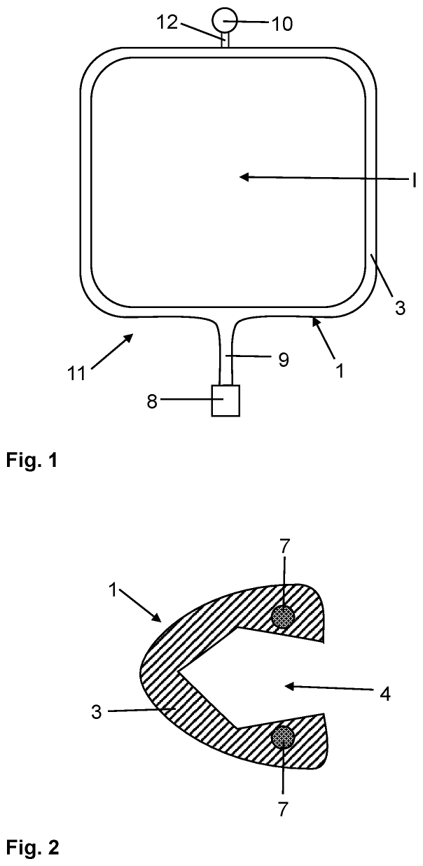

FIG. 1 a plan view of an embodiment of a vacuum system according to the invention,

FIG. 2 a cross-section of a detail of an embodiment of a vacuum ring according to the invention,

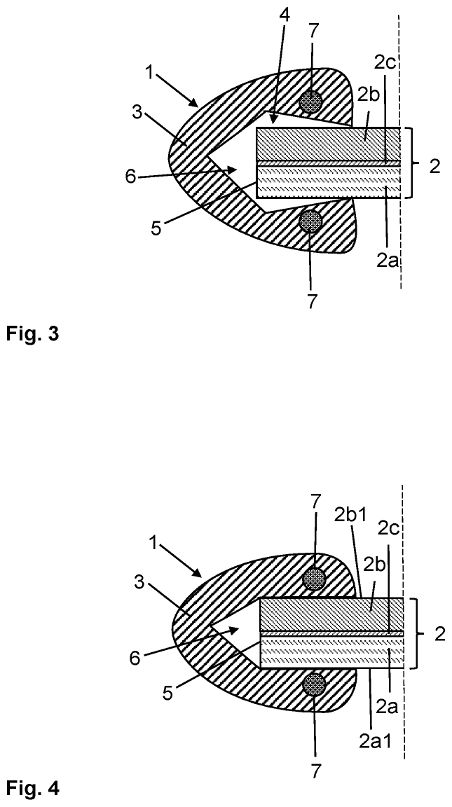

FIG. 3 a cross-section of a detail of an embodiment of a vacuum ring according to the invention at normal pressure, with the stack sequence to be deaerated depicted schematically,

FIG. 4 a cross-section of a detail of an embodiment of a vacuum ring according to the invention after application of a vacuum, with the stack sequence to be deaerated depicted schematically,

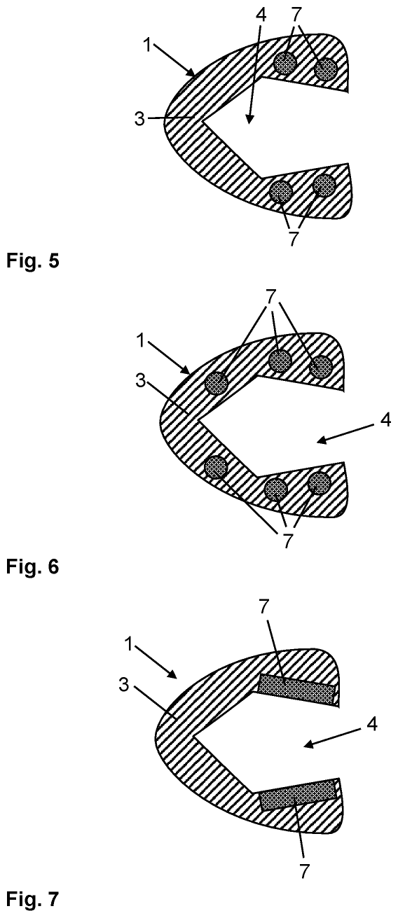

FIG. 5 a cross-section of a detail of an embodiment of a vacuum ring according to the invention,

FIG. 6 a cross-section of a detail of an embodiment of a vacuum ring according to the invention,

FIG. 7 a cross-section of a detail of an embodiment of a vacuum ring according to the invention,

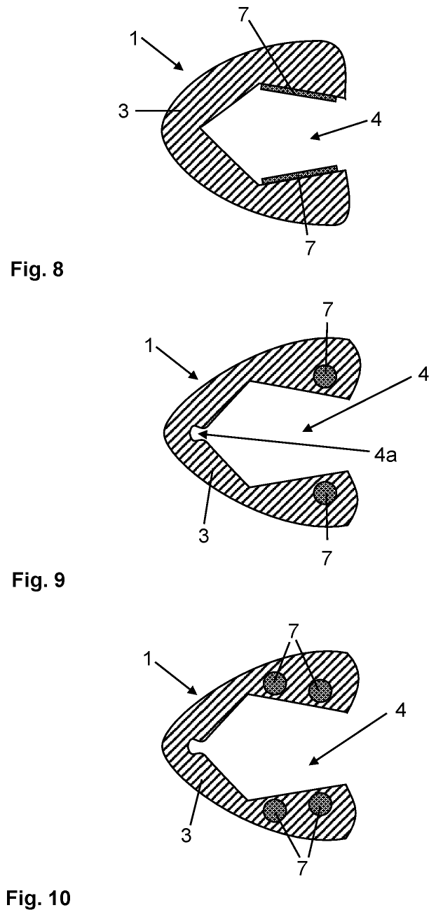

FIG. 8 a cross-section of a detail of an embodiment of a vacuum ring according to the invention,

FIG. 9 a cross-section of a detail of an embodiment of a vacuum ring according to the invention,

FIG. 10 a cross-section of a detail of an embodiment of a vacuum ring according to the invention,

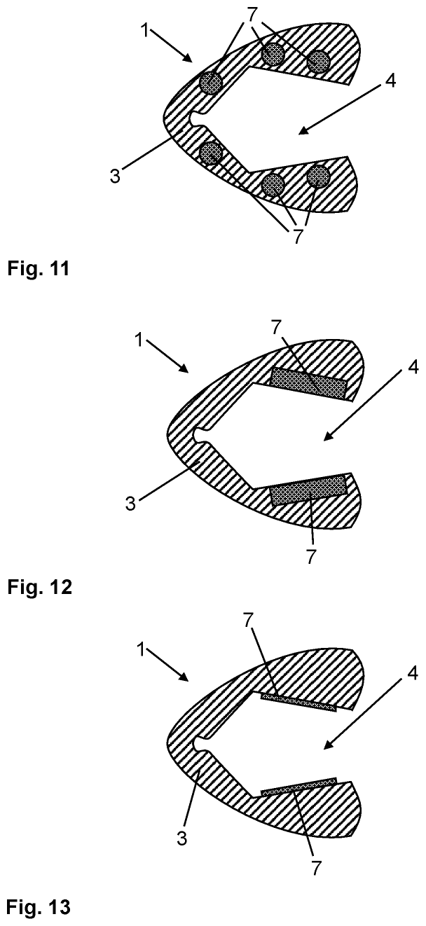

FIG. 11 a cross-section of a detail of an embodiment of a vacuum ring according to the invention,

FIG. 12 a cross-section of a detail of an embodiment of a vacuum ring according to the invention,

FIG. 13 a cross-section of a detail of an embodiment of a vacuum ring according to the invention,

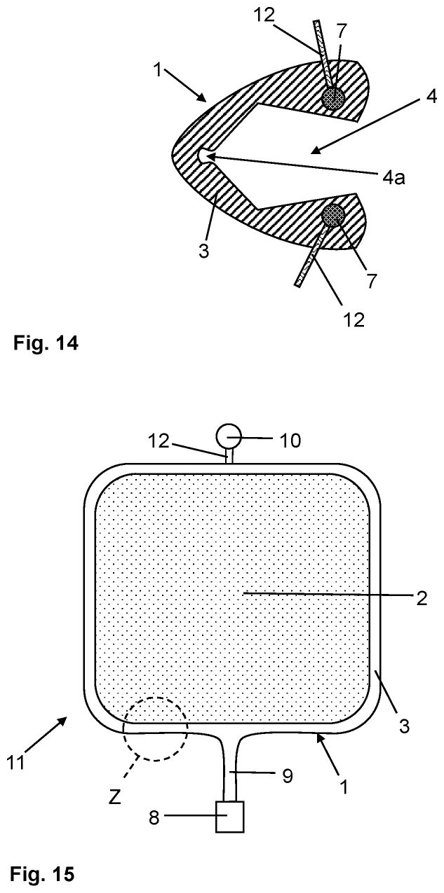

FIG. 14 a cross-section of a detail of another embodiment of a vacuum ring according to the invention, wherein the connection elements of the heating element are depicted,

FIG. 15 a plan view of a vacuum system according to the invention, in which a stack sequence is held,

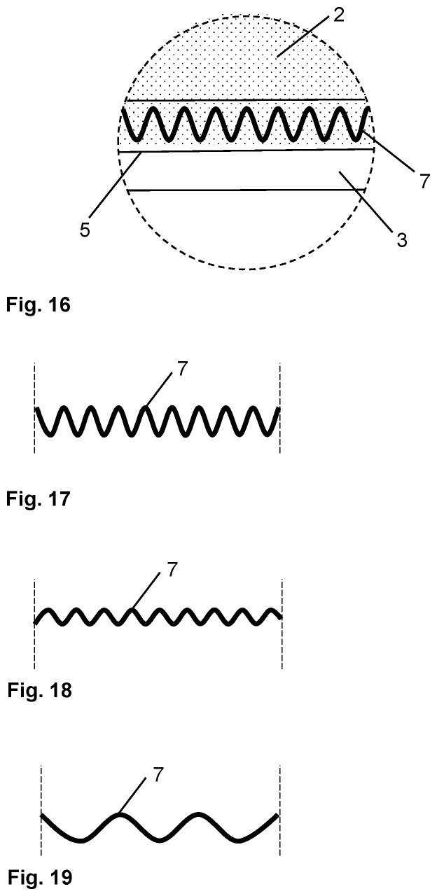

FIG. 16 an enlargement of the region Z of FIG. 15,

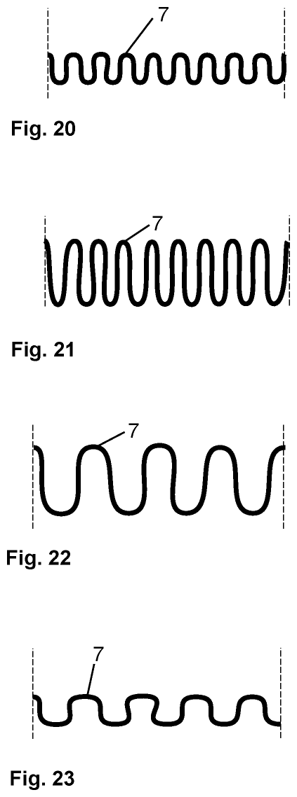

FIGS. 17 to 23 details of various embodiments of wave-shaped and meander-shaped heating elements, and

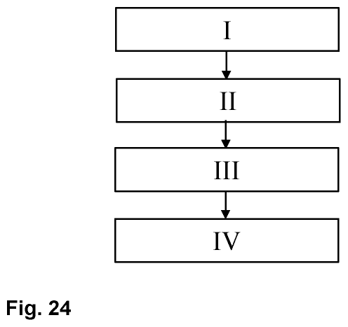

FIG. 24 a flowchart of an embodiment of the method according to the invention.

FIG. 1 depicts a plan view of a vacuum system 11 according to the invention, comprising a vacuum ring 1 according to the invention, a vacuum hose 9, a vacuum pump 8, and a voltage source 10. The vacuum ring 1 comprises a vacuum-stable flexible hose 3, which has the shape of a ring and is connected to a vacuum pump 8 via the vacuum hose 9. The interior of the ring formed by the hose 3 is identified with I in FIG. 1. In the embodiment depicted in FIG. 1, the vacuum ring 1 and the vacuum hose 9 are implemented in one piece, i.e., the vacuum ring 1 and the vacuum hose 9 are manufactured together as one piece. This embodiment is preferred. The vacuum ring 1 has at least one electric heating element 7 (hidden in FIG. 1 by the upper side of the hose 3) that is connected to the voltage source 10 via a connection element 12. In the embodiment depicted in FIG. 1, the vacuum hose 9 together with the vacuum pump 8 and the connection element 12 with the voltage source 10 connected thereto are arranged on different, opposing sides of the vacuum ring 1. However, the arrangement of the vacuum hose 9 with the vacuum pump 8 and of the connection element 12 together with the voltage source 10 can be selected at will. For example, these elements can also be arranged on the same side of the vacuum ring.

FIG. 2 depicts a cross-section of a detail of an embodiment of a vacuum ring 1 according to the invention. In the embodiment depicted in FIG. 2, the vacuum ring 1 has two heating elements 7 that are implemented as wire. One heating element 7 is embedded above the opening 4 and one heating element 7 is embedded below the opening 4 in the mass of the hose 3. The opening 4 has, in the embodiment depicted in FIG. 2, a pentagonal shape. The diameter of the heating element 7 implemented as wires is, for example, 1 mm. In the embodiment depicted in FIG. 2, the vacuum ring 1 has two heating elements 7. However, as explained above, the vacuum ring 1 can, for example, also have only one heating element 7.

FIG. 3 depicts the same cross-section as FIG. 2, wherein, additionally, the stack sequence 2 to be deaerated is schematically depicted and no vacuum has yet been applied. The stack sequence 2 consists, in the embodiment depicted in FIG. 3, of a substrate pane 2a, a cover pane 2b, and a thermoplastic film 2c positioned therebetween. The vacuum ring according to the invention encloses the side edges 5 of the stack sequence 2, the intermediate space between the substrate pane 2a and the film 2c, and the intermediate space between the film 2c and the cover pane 2b and seals this region using vacuum technology. The deaeration channel 6 formed along the side edge 5 can be seen in FIG. 3. From FIG. 3, it can also be seen that the shaping of the opening 4 as a pentagon has an advantageous effect on the formation of a deaeration channel 6.

FIG. 4 depicts the same cross-section as FIG. 3 in the evacuated state, i.e., while a vacuum is applied to the deaeration channel 6. From FIG. 4, it can be seen that when the opening 4 is shaped as a pentagon, an upper part of the hose 3 rests against the upper side 2b1 of the cover pane 2b and a lower part of the hose 3 rests against the lower side 2a1 of the substrate pane 2a when a vacuum is applied and a substantially triangular deaeration channel 6 remains.

FIG. 5 depicts a cross-section of a detail of an embodiment of a vacuum ring 1 according to the invention. In the embodiment depicted in FIG. 5, the vacuum ring 1 has four heating elements 7 that are implemented as wire. Two heating elements 7 are embedded above the opening 4 and two heating elements 7 are embedded below the opening 4 in the mass of the hose 3. The opening 4 has, in the embodiment depicted in FIG. 5, a pentagonal shape. The diameter of the heating elements 7 implemented as wires is, for example, 1 mm.

FIG. 6 depicts a cross-section of a detail of an embodiment of a vacuum ring 1 according to the invention. In the embodiment depicted in FIG. 6, the vacuum ring 1 has six heating elements 7 that are implemented as wire. Three heating elements 7 are embedded above the opening 4 and three heating elements 7 are embedded below the opening 4 in the mass of the hose 3. The opening 4 has, in the embodiment depicted in FIG. 6, a pentagonal shape. The diameter of the heating elements 7 implemented as wires is, for example, 1 mm.

FIG. 7 depicts a cross-section of a detail of an embodiment of a vacuum ring 1 according to the invention. In the embodiment depicted in FIG. 7, the vacuum ring 1 has two heating elements 7 that are implemented as a strip. One heating element 7 is arranged above the opening 4 and one heating element 7 is arranged below the opening 4. In the embodiment depicted in FIG. 7, the heating elements 7 are partially embedded in the mass of the hose 3. One side of the heating elements 7 can thus come into contact with a stack sequence 2 held in the opening 4 (not shown in FIG. 7). The opening 4 has, in the embodiment depicted in FIG. 7, a pentagonal shape. It is also possible for the heating elements 7 that have the form of a strip to be completely surrounded by the mass of the hose 3. This embodiment is, however, not shown in FIG. 7. The width of the heating elements 7 implemented as strips is, for example, 5 mm; and the thickness is, for example, 0.1 mm. In the embodiment depicted in FIG. 7, the vacuum ring 1 has two heating elements 7. However, as explained above, the vacuum ring 1 can, for example, also have only one heating element 7.

FIG. 8 depicts a cross-section of a detail of an embodiment of a vacuum ring 1 according to the invention. In the embodiment depicted in FIG. 8, the vacuum ring 1 has two heating elements 7 that are implemented as a strip. One heating element 7 is arranged above the opening 4 and one heating element 7 is arranged below the opening 4. In the embodiment depicted in FIG. 8, the heating elements are glued onto the mass of the hose 3. One side of the heating elements 7 can thus come into contact with a stack sequence 2 held in the opening 4 (not shown in FIG. 8), in particular in the evacuated state. The opening 4 has, in the embodiment depicted in FIG. 8, a pentagonal shape. The width of the heating elements 7 implemented as strips is, for example, 8 mm; and the thickness is, for example, 0.05 mm. In the embodiment depicted in FIG. 8, the vacuum ring 1 has two heating elements 7. However, as explained above, the vacuum ring 1 can, for example, also have only one heating element 7.

FIG. 9 depicts a cross-section of a detail of an embodiment of a vacuum ring 1 according to the invention. In the embodiment depicted in FIG. 9, the vacuum ring 1 has two heating elements 7 that are implemented as wire. One heating element 7 is embedded above the opening 4 and one heating element 7 is embedded below the opening 4 in the mass of the hose 3. The opening 4 has, in the embodiment depicted in FIG. 9, a substantially pentagonal shape, wherein the corner of the pentagon opposite the side edge 5 when the side edge 5 of a stack sequence 2 is held is implemented as an additional recess 4a of the pentagon. The diameter of the heating elements 7 implemented as wires is, for example, 1 mm. In the embodiment depicted in FIG. 9, the vacuum ring 1 has two heating elements 7. However, as explained above, the vacuum ring 1 can, for example, also have only one heating element 7.

FIG. 10 depicts a cross-section of a detail of an embodiment of a vacuum ring 1 according to the invention. In the embodiment depicted in FIG. 10, the vacuum ring 1 has four heating elements 7 that are implemented as wire. Two heating elements 7 are embedded above the opening 4 and two heating elements 7 are embedded below the opening 4 in the mass of the hose 3. The opening 4 has, in the embodiment depicted in FIG. 10, a substantially pentagonal shape, wherein the corner of the pentagon opposite the side edge 5 when the side edge 5 of a stack sequence 2 is held is implemented as an additional recess 4a of the pentagon. The diameter of the heating elements 7 implemented as wires is, for example, 1 mm.

FIG. 11 depicts a cross-section of a detail of an embodiment of a vacuum ring 1 according to the invention. In the embodiment depicted in FIG. 11, the vacuum ring 1 has six heating elements 7 that are implemented as wire. Three heating elements 7 are embedded above the opening 4 and three heating elements 7 are embedded below the opening 4 in the mass of the hose 3. The opening 4 has, in the embodiment depicted in FIG. 11, a substantially pentagonal shape, wherein the corner of the pentagon opposite the side edge 5 when the side edge 5 of a stack sequence 2 is held is implemented as an additional recess 4a of the pentagon. The diameter of the heating elements 7 implemented as wires is, for example, 1 mm.

FIG. 12 depicts a cross-section of a detail of an embodiment of a vacuum ring 1 according to the invention. In the embodiment depicted in FIG. 12, the vacuum ring 1 has two heating elements 7 that are implemented as a strip. One heating element 7 is arranged above the opening 4 and one heating element 7 is arranged below the opening 4. In the embodiment depicted in FIG. 12, the heating elements 7 are partially partially embedded in the mass of the hose 3. One side of the heating elements 7 can thus come into contact with a stack sequence 2 held in the opening 4 (not shown in FIG. 12). The opening 4 has, in the embodiment depicted in FIG. 12, a substantially pentagonal shape, wherein the corner of the pentagon opposite the side edge 5 when the side edge 5 of a stack sequence 2 is held is implemented as an additional recess 4a of the pentagon. It is also possible for the heating elements 7 that have the form of a strip to be completely surrounded by the mass of the hose 3. This embodiment is, however, not shown in FIG. 12. The width of the heating elements 7 implemented as strips is, for example, 8 mm; and the thickness is, for example, 0.1 mm. In the embodiment depicted in FIG. 12, the vacuum ring 1 has two heating elements 7. However, as explained above, the vacuum ring 1 can, for example, also have only one heating element 7.

FIG. 13 depicts a cross-section of a detail of an embodiment of a vacuum ring 1 according to the invention. In the embodiment depicted in FIG. 13, the vacuum ring 1 has two heating elements 7 that are implemented as a strip. One heating element 7 is arranged above the opening 4 and one heating element 7 is arranged below the opening 4. In the embodiment depicted in FIG. 13, the heating elements are glued onto the mass of the hose 3. One side of the heating elements 7 can thus come into contact with a stack sequence 2 held in the opening 4 (not shown in FIG. 13), in particular in the evacuated state. The opening 4 has, in the embodiment depicted in FIG. 13, a substantially pentagonal shape, wherein the corner of the pentagon opposite the side edge 5 when the side edge 5 of a stack sequence 2 is held is implemented as an additional recess 4a of the pentagon. The width of the heating elements 7 implemented as strips is, for example, 8 mm; and the thickness is, for example, 0.05 mm. In the embodiment depicted in FIG. 13, the vacuum ring 1 has two heating elements 7. However, as explained above, the vacuum ring 1 can, for example, also have only one heating element 7.

FIG. 14 depicts a cross-section of a detail of another embodiment of a vacuum ring 1 according to the invention. The embodiment depicted in FIG. 14 differs from that in FIG. 9, only in that each of the two heating elements 7 has a connection element 12 for connecting to a voltage source. Both heating elements 7 can also be connected to the same voltage source.

It goes without saying that in the embodiments depicted in FIGS. 2 to 13 as well, the heating elements can in each case have a connection element for connecting to a voltage source. In that case, all heating elements of a vacuum ring 1 according to the invention can also be connected to the same voltage source.

FIG. 15 depicts a plan view of a vacuum system 11 according to the invention, in which a stack sequence 2 is held, and FIG. 16 depicts an enlargement of the region Z of FIG. 15. The vacuum ring 1 of the vacuum system 11 depicted in FIG. 15 corresponds, for example, to the embodiment depicted in FIG. 2. To illustrate the arrangement of the stack sequence 2 in the vacuum ring 1, in FIGS. 15 and 16, the stack sequence 2 is a depicted dotted. In the enlargement of the region the Z in FIG. 15, the hose 3 is depicted transparent such that the heating element 7 arranged above the opening 4 can be seen. The heating element 7 is arranged such that it can heat a region adjacent the side edge 5 of the stack sequence 2. The heating element 7 arranged above the opening 4 does not make contact with the side edge 5 of the stack sequence 2. The heating element 7 arranged below the opening 4 cannot be seen in FIG. 16, since it is arranged below the stack sequence 2, which is depicted dotted. However, the heating element 7 arranged below the opening 4 also does not touch the side edge 5 of the stack sequence 2. The heating elements 7 in the embodiment depicted in FIGS. 15 and 16 are implemented as wires that extend in a wave shape over the entire length of the hose 3.

FIGS. 17 to 23 depict, as details, various embodiments of wave-shaped and meander-shaped heating elements 7 that differ from one another, in particular, in terms of wavelength, amplitude, and/or radius of curvature.

FIG. 24 depicts a flowchart of an embodiment of the method according to the invention for deaerating a stack sequence 2.

The method includes, in a first step I, arranging a stack sequence 2. In a second step II, the method includes arranging a vacuum ring 1 according to the invention around the outer side edge 5 of the stack sequence 2. In a third step III, the method includes applying a vacuum to the vacuum ring 1. In a fourth step IV, the method includes applying a voltage to the electric heating element 7. Steps III and IV can even be carried out simultaneously.

### LIST OF REFERENCE CHARACTERS

1 vacuum ring
2 stack sequence
2a substrate pane
2a1 underside of the substrate pane
2b cover pane
2b1 upper side of the cover pane
2c intermediate layer
3 hose
4 opening
4a recess
5 side edge
6 deaeration channel
7 electric heating element
8 vacuum pump
9 vacuum hose
10 voltage source
11 vacuum system
12 connection element
I interior of the ring formed by the hose

1. A vacuum ring for deaerating a stack sequence, comprising a vacuum-stable flexible hose, which is connectable to a vacuum pump, has the shape of a closed ring, and has an opening to the interior such that the vacuum ring can hold an outer side edge of a stack sequence in order to form a deaeration channel along the side edge, wherein the vacuum ring has at least one electric heating element.

2. The vacuum ring according to claim 1, wherein the electric heating element has a connection element for connecting to a voltage source.

3. The vacuum ring according to claim 1, wherein the electric heating element is at least partially embedded in the hose and/or is glued to the hose.

4. The vacuum ring according to claim 1, wherein the electric heating element extends over the entire length of the hose.

5. The vacuum ring according to claim 1, wherein the electric heating element is implemented in the form of a wire or strip.

6. The vacuum ring according to claim 5, wherein the electric heating element is implemented wave-shaped, meander-shaped, or spiral-shaped.

7. The vacuum ring according to claim 1, wherein the electric heating element is arranged directly adjacent the opening.

8. The vacuum ring according claim 1, wherein the electric heating element is arranged outside the deaeration channel formed when an outer side edge of a stack sequence is held in the vacuum ring in the evacuated state.

9. The vacuum ring according to claim 1, wherein the electric heating element is made of a metal or a metal alloy.

10. The vacuum ring according to claim 1, wherein the electric heating element is at least partially coated with an insulating layer.

11. The vacuum ring according to claim 1, wherein the vacuum ring has at least two electric heating elements, of which at least one is arranged above the opening and at least one is arranged below the opening.

12. The vacuum ring according to claim 1, wherein the hose is made of an elastomer.

13. A vacuum system, at least comprising
a vacuum ring according to claim 1,
a vacuum hose, of which one end is connected to the vacuum ring and of which the other end is connected to a vacuum pump, and
at least one voltage source, which is electrically connected to the at least one heating element.

14. A method for deaerating a stack sequence, comprising:
arranging a stack sequence,
arranging a vacuum ring according to claim 1 around the outer side edge of the stack sequence,
applying a vacuum to the vacuum ring, and
applying a voltage to the electric heating element.

15. A method comprising utilizing a vacuum ring according to claim 1 in a method for deaerating a stack sequence.

16. The vacuum ring according to claim 9, wherein the metal or the metal alloy is copper, a copper alloy, a nickel alloy, a nickel-copper alloy, or a nickel-chromium alloy.

17. The vacuum ring according to claim 10, wherein the insulating layer is a non-conductive lacquer, and/or plastic.

18. The vacuum ring according to claim 12, wherein the elastomer is silicone, rubber, or synthetic rubber.

19. The vacuum ring according to claim 18, wherein synthetic rubber is ethylene-propylene-diene rubber (EPDM).

20. The method according to claim 15, wherein the stack sequence is a stack sequence for producing a composite pane or a solar generator.
